(19) United States
(12) Patent Application Publication
(10) Pub. No.: US 2005/0142844 A1
(43) Pub. Date: Jun. 30, 2005

(54) Method for fabricating metal interconnect in semiconductor device

(75) Inventor: Yong Soo Ahn, Bucheon-si (KR)

Correspondence Address: THE LAW OFFICES OF ANDREW D. FORTNEY, PH.D., P.C., 7257 N. MAPLE AVENUE, BLDG. D, 3107, FRESNO, CA, 93720, US

(73) Assignee: DongbuAnam Semiconductor Inc.

(21) Appl. No.: 11/026,916

(22) Filed: Dec. 30, 2004

(30) Foreign Application Priority Data
Dec. 31, 2003 (KR) 10-2003-0101052

(51) Int. Cl. H01L 21/4763; H01L 21/44

(52) U.S. Cl. 438/622; 438/642

(57) ABSTRACT

A method for fabricating a metal interconnect in a semiconductor device is disclosed. A disclosed method comprises: forming a via hole by a damascene process in an interlayer dielectric layer on a substrate; depositing a conducting layer on the substrate including the via hole; forming a photoresist pattern on the conducting layer; and forming a metal interconnect using the photoresist pattern as an etching mask, the lower part of the metal interconnect being wider than the upper part thereof.

### BACKGROUND OF THE INVENTION

1. Field of the Invention

The present disclosure relates generally to a semiconductor fabrication and, more particularly, to a method for fabricating a metal interconnect of a semiconductor device.

2. Background of the Related Art

FIG. 1a is a cross-sectional view illustrating a metallic interconnect fabrication method in accordance with a prior art method.

Referring to FIG. 1a, a via hole connected to a metal interconnect 10 is formed by a damascene process. The via is again connected to a lower structure such as a source/drain and a gate electrode of a transistor. First, the trench for the via is formed by using a photolithography process in a thick interlayer dielectric layer (hereinafter referred to as “IDL”) 12. The via is then completed by a damascene process by which metal is filled in the trench. For a smooth gap fill, the width of the upper part of the trench is wider than the lower part of the trench. A conductive layer for a metal interconnect is then formed on the upper surface of the via. After a photoresist pattern (not shown) is formed to be aligned with the via, a metal interconnect in contact with the via is completed by a dry etch using reactive ions with the pattern as a mask. The reactive ion etching may be performed with Cl₂/BCl₃ as etch gas. The cross section of the metal interconnect fabricated as described above has a rectangular shape.

FIG. 1b is a cross-sectional view illustrating a mis-alignment of a via and a metal interconnect in accordance with a prior art. The mis-alignment may be caused during the patterning process of the metal interconnect, or by some part of design itself. Consequently, the metal material of via can be exposed. In this prior art, corrosion occurs between the metal interconnect and the via according to the composition of the dielectric layer during post-etching processes. Such corrosion is a kind of galvanic corrosion caused by a potential difference, which arises from the Gibbs free energy difference between two adjacent metals. The galvanic corrosion means a corrosion which occurs in a high activity metal due to the potential difference when electrically connected two different metals are exposed to the corosive environment. In other words, oxidation occurs in a low potential energy metal in galvanic corrosion.

The following is a description of the galvanic corrosion when, for example, aluminum (Al) as a metal interconnect and tungsten (W) as via metal are used. The Al and W have been used as main materials for the metal interconnect and the via, respectively, in general device fabrication processes. In corrosion environment using etching gas including chlorine (Cl) to etch the metal interconnect, W which has high potential energy functions as a cathode and Al which has low potential energy compared to W functions as an anode. As a result, the anode of Al is oxidized or corroded to be Al³⁺ and electrons, and the electrons move to the cathode of W. This corrosion can make a hole in the metal interconnect. High contact resistance between the via and the interconnect metal due to the hole deteriorates device operation.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1a is a cross-sectional view illustrating a metal interconnect fabrication method in accordance with a prior art method;

FIG. 1b is a cross-sectional view illustrating an alignment of a via and a metal interconnect in accordance with a prior art method;

FIG. 2a is a cross-sectional view illustrating a metal interconnect fabrication method in accordance with an embodiment of the present invention;

FIG. 2b is a cross-sectional view illustrating the critical dimension of the metal interconnect in accordance with an embodiment of the present invention;

FIG. 2c is a cross-sectional view illustrating a mis-alignment of a via and a metal interconnect in accordance with the present invention.

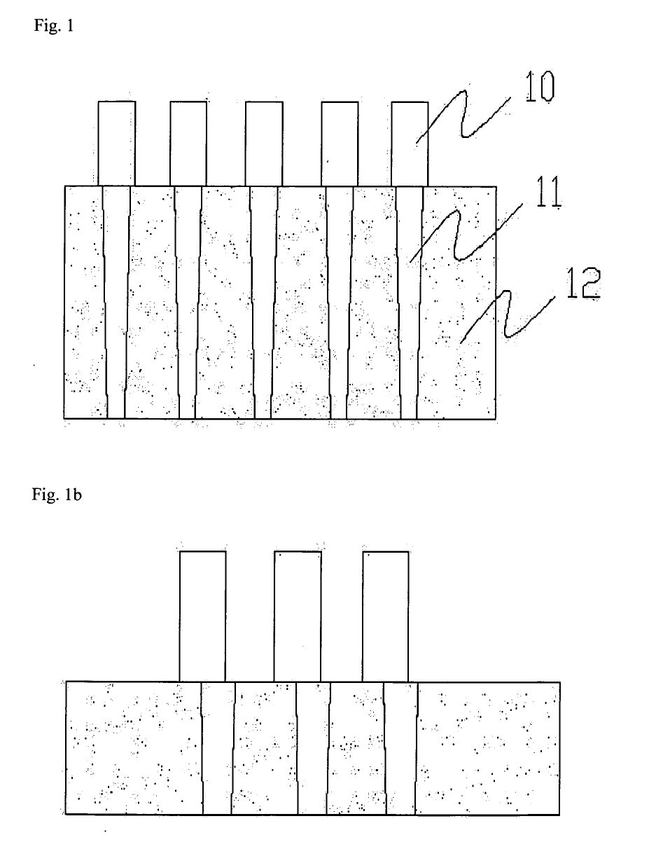

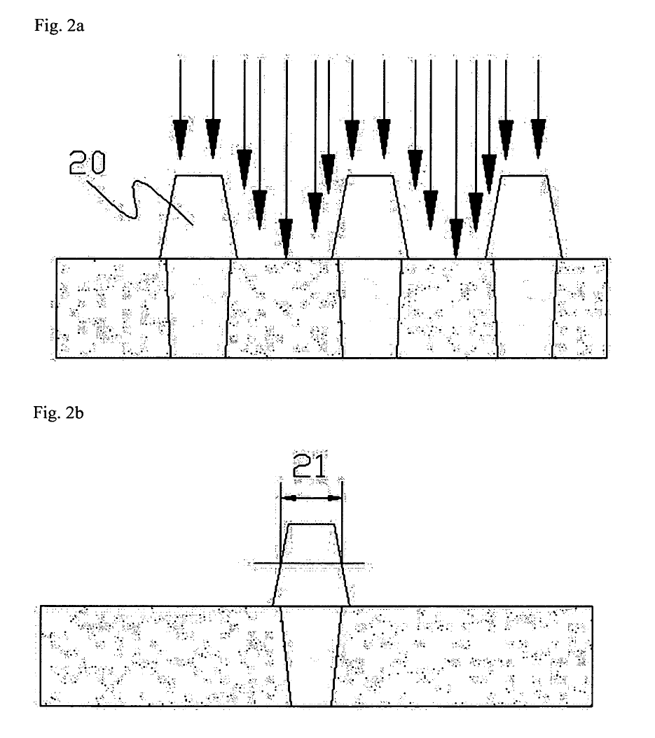

### DETAILED DESCRIPTION OF THE PREFERRED EMBODIMENT

A primary object of the present invention is to make the bottom width of a metal interconnect large to increase align margin, preventing the exposure of a via contact, thereby reducing galvanic corrosion.

To achieve these objects and other advantages and in accordance with the purpose of the invention, as embodied and broadly described herein, the present invention provides a method for fabricating a metal interconnect comprising the steps of: forming a via hole by a damascene process in an interlayer dielectric layer on a substrate; depositing a conducting layer on the substrate including the via hole; forming a photoresist pattern on the conducting layer; and forming a metal interconnect using the photoresist pattern as an etching mask, the lower part of the metal interconnect being wider than the upper part thereof.

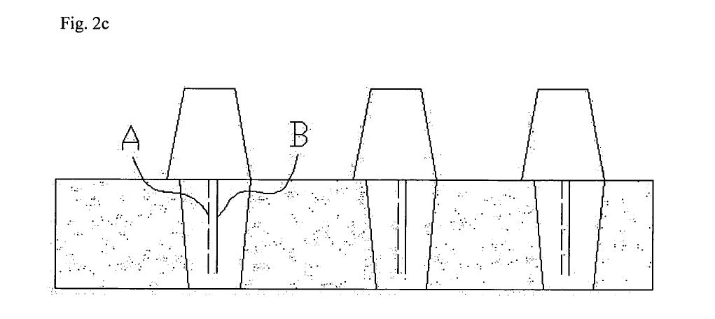

FIG. 2a is a cross-sectional view illustrating a metal interconnect fabrication method in accordance with an embodiment of the present invention. The formation of a via and a conductive layer is conducted as in the prior art. Next, a metal interconnect is formed in a ladder shape. In order to enlarge the lower part of the metal interconnect, plasma power is adjusted during the etching process for the metal interconnect. In detail, the bias power of a plasma chamber is gradually changed in at least two steps, preferably three steps. The conventional process employs a constant bias power using etching gas like Cl₂ or BCl₃. But, the present invention uses a dry etching while reducing the bias power in three steps such as 120 kW, 100 kW and 80 kW. As the bias power becomes weak during the etching for the metal interconnect, the degree of etching decreases and, consequently, the metal interconnect is formed in a ladder shape. FIG. 2b illustrates the critical dimension of the sloped metal interconnect 21. The critical dimension of the metal interconnect is measured at the 50% point between the upper and the lower part of the metal interconnect.

FIG. 2c is a cross-sectional view illustrating a mis-alignment of the via and the metal interconnect. The dotted line ‘A’ is the center axis of the via in normal alignment. The solid line ‘B’ is the center axis of the via in mis-alignment. As described above, the lower part of the metal interconnect is formed wider compared to the prior art. The via under the metal interconnect is not exposed even when the alignment of the metal interconnect is inaccurate. Accordingly, the galvanic corrosion caused by the contact between the metal of the interconnect and the metal of the via may be suppressed. The margin of alignment increases in an exposure process compared to the prior art and, therefore, the efficiency of the exposure process also increases. The upper space between the metal interconnects is wider than that between the rectangular metal interconnects according to the prior art. This feature provides an additional advantage for a gap fill process by an insulating material, increasing the gap fill efficiency of an insulating material into the trench between the metal interconnects.

Accordingly, the present invention makes the bottom width of a metal interconnect larger to increase align margin, preventing the exposure of a via contact, thereby reducing galvanic corrosion. The margin of alignment increases in an exposure process compared to the prior art and, therefore, the efficiency of the exposure process also increases. The upper space between the metal interconnect is wider than that between the rectangular metal interconnects according to the prior art. This feature provides an additional advantage for a gap fill process by an insulating material, increasing the gap fill efficiency of an insulating material into the trench between the metal interconnect.

It is noted that this patent claims priority from Korean Patent Application Serial Number 10-2003-0101052, which was filed on Dec. 31, 2003, and is hereby incorporated by reference in its entirety.

Although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

1. A method for fabricating a metal interconnect comprising the steps of:
forming a via hole by a damascene process in an interlayer dielectric layer on a substrate;
depositing a conducting layer on the substrate including the via hole;
forming a photoresist pattern on the conducting layer; and
forming a metal interconnect using the photoresist pattern as an etching mask, the lower part of the metal interconnect being wider than the upper part thereof.

2. A method as defined by claim 1, wherein the metal interconnect is formed by a dry etching.

3. A method as defined by claim 2, wherein the dry etching is performed by using plasma including reactive ions while gradually reducing a bias power in at least two steps.
